(19) United States
(12) Patent Application Publication
(10) Pub. No.: US 2021/0175325 A1
(43) Pub. Date: Jun. 10, 2021

(54) DIFFUSION BARRIERS MADE FROM MULTIPLE BARRIER MATERIALS, AND RELATED ARTICLES AND METHODS

(71) Applicant: ENTEGRIS, INC., Billerica, MA (US)

(72) Inventor: Carlo WALDFRIED, Middleton, MA (US)

(21) Appl. No.: 17/115,196

(22) Filed: Dec. 8, 2020

Related U.S. Application Data
(60) Provisional application No. 62/945,602, filed on Dec. 9, 2019.

(51) Int. Cl. H01L 29/06; H01L 29/26

(52) U.S. Cl. CPC H01L 29/0638; H01L 29/0665; H01L 29/26

(57) ABSTRACT

Described are diffusion barriers that are effective to inhibit the flow and release of impurities present in a solid material, from a surface of the solid material, as well articles having a diffusion barrier on a surface thereof, methods of preparing articles that include a diffusion barrier on a surface, equipment that includes an article having a diffusion barrio on a surface, and methods of using the articles and equipment; the diffusion barrier include at least two different barrier materials.

### CROSS-REFERENCE TO RELATED APPLICATION

This application claims the benefit of and priority to U.S. Provisional Application No. 62/945,602 filed on Dec. 9, 2019, and which is incorporated herein by reference in its entirety for all purposes.

### TECHNICAL FILED

The present description relates to diffusion barriers that inhibit the release of impurities present in a solid material or from a surface of the solid material, as well to articles having a diffusion barrier on a surface thereof, methods of preparing articles that include a diffusion barrier on a surface, equipment that includes an article having a diffusion barrier on a surface, and methods of using the articles and equipment.

### BACKGROUND

Semiconductor and microelectronic device manufacturing processes require highly pure processing environments in which to contain a workpiece for processing. Examples of semiconductor processing steps involve adding an amount of highly pure material to a semiconductor wafer that is made of highly pure material, having a highly precise chemical makeup.

One example of a common semiconductor process step is a deposition process by which a precise amount of a desired (highly pure) material is deposited onto a semiconductor substrate by chemical vapor deposition, atomic layer deposition, physical vapor deposition, or the like. The processing environment, i.e., the environment in which the deposition takes place, is a vacuum environment that must be highly free of contaminants, impurities, particulates, etc., because any of these unwanted materials may become deposited onto the substrate as an unwanted impurity. The processing environment is contained by a process chamber that is evacuated other than to contain the semiconductor substrate, gaseous (including plasma, ionic) process materials necessary to perform the deposition, and a minimum of any other materials or structures.

A different example of a semiconductor manufacturing process is an ion implantation process by which ions are caused to penetrate a surface of a semiconductor substrate to add the ions to the material of the semiconductor substrate. A precise amount of the implanted ions (sometimes referred to as “dopants”) is added by to the semiconductor substrate material by bombarding the substrate with the ions (e.g., by an ion beam, or by ion immersion techniques). The substrate again has a precise and pure (as to its intended constituents) chemical makeup, and the ions (dopant) added to the substrate surface must also be highly pure. The processing environment is contained by a process chamber (e.g., an ion implantation chamber or a surface modification chamber) that is evacuated other than to contain the semiconductor substrate, ions for implantation, any other process fluids necessary to perform the implantation, and a minimum of any other materials, which are considered impurities or contaminants.

Still other examples of semiconductor manufacturing steps that are performed within a highly purified processing environment that is as free as possible from impurities are: annealing processes, etching processes (e.g., plasma etching), cleaning steps, as well as others.

A structure that defines and contains a processing environment of a semiconductor manufacturing tool can be referred to as a process chamber (specific examples are an anneal chamber, a deposition chamber, an ion implantation chamber, an etch chamber). The process chamber defines an interior space that contains the processing environment, and additionally contains appurtenant structures and devices for performing a specific semiconductor manufacturing process. The process chamber is made of and contains components (a.k.a. “process chamber components”) that define the processing environment (e.g., sidewalls), and components that allow the process chamber and a semiconductor processing tool that contains the process chamber to perform a desired semiconductor manufacturing process. In addition to sidewalls, the process chamber components include devices, equipment, and parts to contain or support a workpiece (e.g., semiconductor wafer), to deliver process materials to the chamber, or to monitor the process being performed within the chamber. Examples include the chamber walls, flow conduits (e.g., flow lines, flow heads, and the like), fasteners, trays, supports (e.g., a platen or “chuck” to support a workpiece), ports, electronics, monitoring devices, as well as various other structures that are used to support a workpiece, to deliver or contain a process material relative to the process chamber, or to otherwise perform or monitor a process being performed within the process chamber.

To reduce the amount of impurities within a processing environment, process chamber components should not introduce an impurity onto the processing environment, either before, during, or after use. A process chamber component should be free of surface impurities. Also, to the extent that a material of a process chamber component contains impurities that may be released (e.g., outgassed) from the material over time, e.g., impurities adsorbed within the solid structure of the material, these impurities should not be allowed to be released into the processing environment.

Various solid materials have been used to form process chamber components for use in semiconductor manufacturing tools. Useful materials can generally include metals and metal alloys (e.g., aluminum (including aluminum alloys), stainless steel); minerals such as quartz; ceramics; glass; silicon materials; and various polymers. While these solid materials can be prepared to high levels of purity (low levels of impurities), even those of the highest purity levels will have some amount of impurity content. Common examples of known impurities are metals, sometimes referred to as “trace metal impurities,” which include Fe, Co, Ni, Zn, Mg, Mn, Cu, Na, Ca, K, etc. These trace metal impurities are known to diffuse through a solid material that contains the trace metal impurity, and to be released from the material surface over time, especially at elevated temperatures. In a semiconductor manufacturing environment, even such minute amounts of these released impurities can be detrimental to a workpiece. Semiconductor processing is highly sensitive to impurities such as trace metals, as these materials affect performance and yield of devices and manufacturing processes.

Accordingly, to prevent the release of trace metal impurities from a solid material of a process chamber component, into a semiconductor processing environment, the process chamber components have been prepared to include a diffusion barrier at a surface, typically made of a metal oxide. The diffusion barrier resists passage of a trace metal impurity from a surface of the solid material into an adjacent vacuum or directly onto the semiconductor workpiece. The diffusion barrier in effect is designed to cover or “encapsulate” the process chamber component in an attempt to confine all impurities into the bulk material. Two examples of materials for these diffusion barriers are aluminum oxide (Al₂O₃) and tantalum oxide (Ta₂O₅).

### SUMMARY

Recently, advances in semiconductor processing tools and semiconductor processing methods have resulted in an increased need to prevent impurities such as trace metal impurities from being released from a process chamber component of a semiconductor processing tool, into a processing environment.

As one factor, some types of semiconductor processing methods are being performed at higher temperatures. Ion implantation methods, for example, are newly being performed at increasingly higher temperatures, including temperatures significantly above room temperature, e.g., over 300, 400, or 500 degrees Celsius. Still higher ion implantation processing temperatures may be used in future processes, such as temperatures up to or in excess of 600 or 700 degrees Celsius. Similarly, deposition methods (e.g., chemical vapor deposition, physical vapor deposition, atomic layer deposition) and annealing steps may be performed at temperatures at or above 400, 500, or 600 degrees Celsius. At these high process temperatures, impurities that are present in a material of a process chamber component will have higher diffusion rates within the material, and have a higher rate of release from a surface of the material.

Also, in an ongoing and increasing manner, the level of sensitivity of semiconductor devices to trace metal impurities has increased. Smaller sizes of microelectronic device features, and higher performance expectations in terms of higher speeds and reduced errors, reduce the tolerance levels for impurities in a finished device.

The disclosure relates to diffusion barriers that inhibit the release of impurities from a surface of a solid material that contains the impurities. The disclosure also relates to: solid bodies that include the diffusion barrier on a surface thereof, methods of preparing a solid body that includes a diffusion barrier on a surface; process chamber components and processing equipment that includes a process chamber component that includes a solid body having a diffusion barrier; and methods of using such process chamber components and processing equipment. The diffusion barrier contains at least two different barrier materials, and may be in the form of a multi-layer diffusion barrier, a laminate, or a composite. One or more of the barrier materials may be an oxide, nitride, or fluoride of yttrium; one or more of the barrier materials may be an oxide, nitride, or fluoride of aluminum; one or more of the barrier materials may be an oxide, nitride, or fluoride of titanium; one or more of the barrier materials may be an oxide, nitride, or fluoride of zirconium; and one or more of the barrier materials may be an oxide, nitride, or fluoride of tantalum. When referring to a barrier material as an “oxide,” “nitride,” or “fluoride” of one of the metals, these terms specifically include barrier materials may include a nitride-oxide, nitride-fluoride, or a oxide-fluoride of one of the metals, such as MₓOₓN_{y}, MOF (M is one of the listed metals), e.g., YₓOₓN_{y} or YOF, etc..

In one aspect, the disclosure relates to a diffusion barrier that contains at least two barrier materials. The barrier materials are selected from: an yttrium compound selected from an oxide, nitride, or fluoride of yttrium; an aluminum compound selected from an oxide, nitride, or fluoride of aluminum; a titanium compound selected from an oxide, nitride, or fluoride of titanium; a zirconium compound selected from an oxide, nitride, or fluoride of zirconium; and a tantalum compound selected from an oxide, nitride, or fluoride of tantalum.

In another aspect, the disclosure relates to an article that includes a substrate having a diffusion barrier. The diffusion barrier includes at least two barrier materials selected from: an yttrium compound selected from an oxide, nitride, or fluoride of yttrium; an aluminum compound selected from an oxide, nitride, or fluoride of aluminum; a titanium compound selected from an oxide, nitride, or fluoride of titanium; a zirconium compound selected from an oxide, nitride, or fluoride of zirconium; and a tantalum compound selected from an oxide, nitride, or fluoride of tantalum.

### BRIEF DESCRIPTION OF THE DRAWINGS

The disclosure may be more completely understood in consideration of the following description of various illustrative embodiments in connection with the accompanying drawings.

FIG. 1 illustrates an example of a prior art solid body with diffusion barrier.

FIG. 2 illustrates an example of a solid body with diffusion barrier as described.

FIGS. 3A, 3B, and 3C illustrate specific example embodiments of solid bodies with diffusion barrier as described.

FIG. 4 illustrates an example of an electrostatic chuck with a diffusion barrier as described.

While the disclosure is amenable to various modifications and alternative forms, specifics thereof have been shown by way of example in the drawings and will be described in detail. It should be understood, however, that the intention is not to limit aspects of the disclosure to the particular illustrative embodiments described. On the contrary, the intention is to cover all modifications, equivalents, and alternatives falling within the spirit and scope of the disclosure.

### DETAILED DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The term “about” generally refers to a range of numbers that is considered equivalent to the recited value (e.g., having the same function or result). In many instances, the term “about” may include numbers that are rounded to the nearest significant Fig.

Numerical ranges expressed using endpoints include all numbers subsumed within that range (e.g. 1 to 5 includes 1, 1.5, 2, 2.75, 3, 3.80, 4 and 5).

The following detailed description should be read with reference to the drawings in which similar elements in different drawings are numbered the same. The detailed description and the drawings, which are not necessarily to scale, depict illustrative embodiments and are not intended to limit the scope of the invention. The illustrative embodiments depicted are intended only as exemplary. Selected features of any illustrative embodiment may be incorporated into an additional embodiment unless clearly stated to the contrary.

The following description relates to diffusion barriers that are effective to inhibit the release of an impurity from a surface of a solid body that contains the impurity or from solid bodies that include the diffusion barrier on a surface thereof; to methods of preparing a solid body that includes a diffusion barrier on a surface; to process chamber components and processing equipment that includes a process chamber component that includes a solid body having a diffusion barrier; and to methods of using such process chamber components and processing equipment.

Diffusion barriers can be useful as part of a structure, article, device, or a component of process equipment or apparatus for which a need or desire exists to prevent an impurity (e.g., a trace metal impurity) that is present in a solid body from being released from the solid body into an adjacent or connected environment where the presence of the impurity or other material is undesired, disadvantageous, or potentially harmful. A diffusion barrier is located at an interface or surface of the solid body and has a composition and structure to effectively inhibit or prevent passage of the impurity that is present as an adsorbed impurity within the solid body, from the solid body to the adjacent environment by diffusion and outgassing.

In example applications, a diffusion barrier can be useful with semiconductor processing tools and semiconductor processing methods to prevent impurities that are present in a process chamber component of the semiconductor processing tool from being released from a surface of the process chamber component into a processing environment. Release of the impurity would place the impurity in a highly pure processing environment contained by the processing tool. Once present in the processing environment, the impurity is undesirable due to the potential that the impurity may contact and become incorporated into a workpiece (e.g., a semiconductor wafer) that is being processed using the semiconductor processing tool.

Examples of solid materials used as solid bodies of process chamber components of semiconductor processing tools include metals (including alloys such as stainless steel and aluminum alloys), ceramics, glass, polymers, and quartz. These solid materials, depending on their specific composition, contain various different types of trace metal impurities, such as one or more of iron, cobalt, nickel, zinc, copper, magnesium, manganese, sodium, calcium, potassium, boron, beryllium, aluminum, titanium, vanadium, selenium, strontium, arsenic, molybdenum, cadmium, tin, tungsten, mercury, lead, barium, antimony, as well as others. These impurities have the potential to diffuse from the solid material and evolve from a surface of the solid material (e.g., “outgas”) into an adjacent environment or directly onto the semiconductor workpiece. This is particularly true at high temperatures and high vacuum conditions sometimes used in certain semiconductor processing methods.

A diffusion barrier, as described, includes two or more different barrier materials that together inhibit the diffusion and release of two or more different types of impurities from a solid body. According to example diffusion barriers, one of the two barrier materials can be effective to act as a barrier against a first impurity, and a second of the two barrier materials can be effective to act as a barrier against at least one additional impurity (referred to as a “second impurity”) that is different from the first impurity and for which the first barrier material is a less effective barrier, e.g., in terms of diffusion rate through the barrier material.

The diffusion barrier is made from at least two different barrier materials, each of which is an oxide, nitride, or fluoride of yttrium, aluminum, titanium, zirconium, or tantalum (these materials specifically including nitride-oxide, nitride-fluoride, and oxide-fluoride compounds of any of the metals). In more detail, example diffusion barriers may be made from at least two different barrier materials, each barrier material being a metal-containing compound, with the metal being yttrium, aluminum, titanium, zirconium, or tantalum, e.g., a diffusion barrier may be made from two different compounds selected from an yttrium compound, an aluminum compound, a titanium compound, a zirconium compound, and a tantalum compound, with each compound being an oxide, fluoride, or nitride of the metal. One of the barrier materials may be an oxide, nitride, or fluoride of yttrium; one of the barrier materials may be an oxide, nitride, or fluoride of aluminum; one of the barrier materials may be an oxide, nitride, or fluoride of titanium; one of the barrier materials may be an oxide, nitride, or fluoride of zirconium; and one of the barrier materials may be an oxide, nitride, or fluoride of tantalum. In all instances, the terms metal oxide, metal fluoride, and metal nitride include a metal nitride-oxide, metal nitride-fluoride, or metal oxide-fluoride, such as YₓOₓN_{y} or YOF and similar compounds of aluminum, titanium, zirconium, and tantalum.

Two different barrier materials of a diffusion barrier may be based on two different metals (yttrium, aluminum, titanium, zirconium, or tantalum), e.g., the diffusion barrier may be a combination of an aluminum-containing compound and an yttrium-containing compound, e.g., alumina and yttria, or a combination of an aluminum-containing compound and a zirconium-containing compound, such as alumina and zirconia, etc. Alternately, two different barrier materials may each contain the same metal, e.g., barrier materials may include two different metal-containing compounds that both are based on the same metal selected from yttrium, aluminum, titanium, zirconium, or tantalum. For example, the diffusion barrier may be a combination of alumina and aluminum fluoride, or a combination of yttria and yttrium fluoride, or titania and titanium fluoride, etc.

The two or more different barrier materials can be selected to provide a diffusion barrier that has effective barrier properties for multiple different impurities present in a solid material of a solid body. Different types of solid materials (e.g., aluminum, stainless steel, glass, or ceramic) contain different combinations of trace metal impurities; example metal alloys, glass, or ceramic may include two or more of: iron, cobalt, nickel, zinc, copper, magnesium, manganese, sodium, calcium, potassium, as well as others. Different barrier materials may be effective as a barrier to prevent passage of one or more of these, but may be less effective or ineffective to prevent passage of other impurities (from the stated list, or not). A diffusion barrier of the present description may include a first barrier material that is effective to act as a barrier material to prevent passage of a first impurity, but that is not effective or that is much less effective to act as a barrier material to prevent passage of a different (second) impurity; the diffusion barrier can include a different (second) barrier material that is effective (e.g., more effective than the first barrier material) to prevent passage of the second impurity.

As just one example, some solid materials may include a first impurity from the group of: iron, cobalt, nickel, or copper; and a second impurity from the group of: magnesium, sodium, calcium, or potassium. Certain barrier materials may be effective as a barrier against one or more impurities of the first group, but none of the second group. Other barrier material may be effective as a barrier against one or more impurities of the second group. A useful diffusion barrier of the present description can include a first barrier material that is an effective barrier for iron, cobalt, nickel, or copper, and a second barrier material that is effective as a barrier against magnesium, sodium, calcium, or potassium. With more specificity, alumina can be effective as a barrier material for iron, cobalt, nickel, or copper, but is not as effective as a barrier against magnesium, sodium, calcium, or potassium. An effective diffusion barrier may include a alumina as first barrier material to inhibit flow of iron, cobalt, nickel, or copper, and a second barrier material (e.g., a titanium compound, a zirconium compound, an yttrium compound, or a tantalum compound) that is effective as a barrier against magnesium, sodium, calcium, or potassium.

Where a first barrier material is suitably effective as a barrier material for a first impurity but not suitably effective as a barrier material for a second impurity, the second barrier material can be one that is more effective as a barrier for the second impurity. The second barrier material may be at least twice as effective, preferably 5 or 10 times more effective as a barrier material to the second impurity, compared to the first barrier material. In terms of diffusion rate of an impurity through a barrier material, a diffusion rate of the second impurity through the second barrier material can be one half, one fifth (20 percent), or one tenth (10 percent) of the diffusion rate of the second impurity through the first barrier material.

A diffusion barrier may also include a third barrier material that functions to improve the general or overall barrier properties of a diffusion barrier that contains a first and a second barrier material. A third barrier material may reduce a diffusion rate of one or more impurities when used in combination with the first two barrier properties. In specific examples, a third barrier material can be one that is increases the effectiveness of the diffusion barrier for at least one impurity, compared to a comparable diffusion barrier that includes only first and second barrier materials. The third barrier material added to a diffusion barrier made from a first and a second barrier material may reduce a diffusion rate of an impurity by at least 10, 20, or 50 percent compared to a comparable diffusion barrier that includes only first and second barrier materials.

A diffusion barrier or a diffusion barrier material as described performs to at least a useful standard of performance required for a diffusion barrier in a specific environment, application, or impurity. For use in a semiconductor processing tool, a diffusion barrier or a diffusion material as described can preferably exhibit effectiveness as a diffusion barrier based on an elemental impurity concentration gradient across the diffusion barrier layer. For example, at an effective operating temperature of a semiconductor processing tool (e.g., as identified herein) a diffusion barrier will produce a concentration gradient measured across the diffusion barrier layer; the concentration gradient can be defined as a difference in concentration of an elemental impurity on one side of the diffusion barrier compared to a concentration of the same elemental impurity on a second side of the diffusion barrier, particularly in the context of a semiconductor processing tool: a difference in concentration of the impurity in a solid body having the diffusion barrier compared to a concentration of the same elemental impurity at the diffusion barrier layer surface adjacent the gaseous atmosphere (e.g., a process chamber of semiconductor processing tool). According to example diffusion barriers, in example semiconductor processing tools, a concentration gradient may be in a range of a 1/10^{th}, 1/100^{th}, or 1/1000^{th}, when considered as the concentration of an impurity at the diffusion barrier layer surface of the process chamber relative to the concentration of the impurity in the solid body. Specifically, a useful or preferred barrier may result in an impurity concentration in a process chamber that is 1/10^{th}, 1/100^{th}, or 1/1000^{th}, of the concentration of the same impurity on the process chamber at operating temperature.

When used for various types of process chamber components and uses, e.g., as a coating of a process chamber component for use in a particular processing method, a diffusion barrier may also desirably exhibit one or more additional physical properties such as: chemical resistance or chemical inertness, a desired electrical property, and stability over time at high operating temperatures such as operating temperatures of semiconductor processing tools described herein.

For certain uses, a high degree of resistance to chemical degradation, i.e., chemical inertness, can be desired for a process chamber component that is used in a plasma etching tool, in an ion implantation tool, or within an process chamber of another type of semiconductor processing tool that uses reactive process materials such as a plasma, an ionic material, a base or acid, or an otherwise reactive vapor, especially at a high temperature. For this purpose, a process chamber component that includes a diffusion barrier as described, disposed on a solid body, may optionally include an additional layer of a chemically-resistant material adjacent to the solid body surface or the diffusion barrier. Examples of chemically-resistant materials are known, including chemically resistant layers useful in semiconductor processing tools, with certain specific examples including, but not limited to metal oxides and metal fluorides such as aluminum oxide formed by anodization; yttrium oxide; multi-layer combinations of aluminum oxide and yttrium oxide, as well as others.

A diffusion barrier as described can preferably exhibit a highly amorphous morphology. For example, as determined by use of x-ray diffraction techniques, a useful or preferred diffusion barrier of the present description can have a noticeably reduced impurity diffusion rate in a substantially amorphous diffusion barrier layer, wherein the full width half max (FWHM) of the diffusion barrier's XRD peaks is wider than 2.5 degree 2-theta by x-ray diffraction.

A diffusion barrier as described can be particularly useful or advantageous when used at a relatively high processing temperature at which diffusion rates of trace metal impurities will be increased. Various semiconductor processing methods are performed at a relatively high process temperature, such as a temperature above 300 or 400 degrees Celsius. Ion implantation methods may be performed at a temperature in excess of 300, 400, or 500 degrees Celsius, or even up to or in excess of 600 or 700 degrees Celsius. Deposition methods (e.g., atomic layer deposition, chemical vapor deposition, physical vapor deposition, and the like) as well as annealing processes may be performed at temperatures at or above 300, 400, 500, or 600 degrees Celsius. At these relatively high processing temperatures, diffusion rates of trace metal impurities present in a solid material of a process chamber component will increase. With the increased diffusion rate, greater amounts of the impurities will diffuse through and be released from a surface of the solid material and will enter a processing environment of a semiconductor process tool. Thus, at these relatively high processing temperatures, effective diffusion barriers have high value.

A diffusion barrier as described can have a form of a deposited coating made of two or more barrier materials as described, provided on a surface of a solid body. The barrier materials may be present in any form, with examples being: a “multi-layer” form that includes from two to several (e.g., 2 to 10) discrete and identifiable layers of different barrier materials; a “laminate” form that includes a higher number of discrete and identifiable layers of different barrier material, such as a number in a range of tens, hundreds, or thousands; and a “composite” material that contains two or more different types of barrier materials, with the different barrier materials not being formed into complete or contiguous layers (e.g., islands of deposited material).

Generally, as non-limiting examples, a thickness of a single identifiable layer of a diffusion barrier may be in a range from of less than 1 nanometer, e.g., about 0.1, 0.5, 1, 2, 5, or 10 nanometers, up to 100, 500, 800, or 900 nanometers (0.9 micron). A total thickness of a diffusion barrier may be in a range 10 nanometers to 1000 nanometers (1 micron).

For a diffusion barrier that includes discrete layers of different barrier materials, e.g., a multi-layer diffusion barrier or a laminate diffusion barrier, each separate layer can exhibit a coefficient of thermal expansion (CTE) that will allow for stability of the multi-layer diffusion, e.g., over a lifetime of temperature cycles. Desirably, a coefficient of thermal expansion of each layer can be similar to a coefficient of thermal expansion of an adjacent layer, such as within a range of 100, 75, 50, 20, or 10 percent or less. For a multi-layer diffusion barrier or a laminate diffusion barrier, every layer of the diffusion barrier can preferably have a coefficient of thermal expansion that is within 100, 75, 50 20, or 10 or less percent of the coefficients of thermal expansion of any adjacent layer, i.e., two adjacent layers for all internal layers and a single adjacent layer for top and bottom layers. By these selections, the layers of a multi-layer diffusion barrier are arranged and ordered in a manner that accounts for potentially high thermal stresses that will be imparted on the diffusion barrier during use.

Example diffusion barriers referred to herein as “multi-layer” diffusion barriers include diffusion barriers that are made of two or more, e.g., 2, 3, 5, or up to 10, 20, or 30 separate layers, each layer being made of a single barrier material, with the diffusion barrier containing layers made of at least two different barrier materials. Each layer is continuous, has a discernible thickness, and is made of a single barrier material having a relatively high level of purity, e.g., at least 90, 95, 98, or 99 percent by weight of a single barrier material as described herein. The layers of the diffusion barrier can be of any useful thickness, such as a thickness in a range of from 1, 2, 5, or 10 nanometers up to 10, 100, 500, 800, or 900 nanometers; e.g., from 2 to 5 layers each having a thickness in a range from 2 to 10 nanometers. A total thickness of this type of diffusion barrier can be any useful thickness, example thicknesses being in a range of from 5 or 10, up to 500, 750, or 1000 nanometers.

Thicknesses of each layer of a multi-layer diffusion barrier may be the same, approximately the same, or may be different. Examples of multi-layer diffusion barriers may include barrier material layers that exhibit a pattern of different thicknesses, such as three repeating layers, A, B, and C, each having a different thickness, such as: thicknesses of (5 nm A, 20 nm B, and 2 nm C)×N, repeated over a number (N) of repetitions (N may be from 1 to 10). Other examples may be three layers, A, B, and C, including a single barrier material layer A having a thicknesses of 50 nm in combination with multiple repeating barrier material layers of B and C: (5 nm B and 3 nm C)×N repeated over a number (N) of repetitions ((N) may be from 1 to 10).

Example multi-layer diffusion barriers that contain from 2 to 10 separate layers can be made of two or more different barrier materials having a high level of purity, selected from: an oxide, nitride, or fluoride of yttrium; an oxide, nitride, or fluoride of aluminum; an oxide, nitride, or fluoride of titanium; an oxide, nitride, or fluoride of zirconium; and an oxide, nitride, or fluoride of tantalum. The multi-layer diffusion barrier may be prepared by any method of depositing the multiple layers, e.g., individually, onto a solid material, such as by physical vapor deposition, chemical vapor deposition, atomic layer deposition, any derivative of such a deposition method, or other known coating and deposition techniques.

Other examples of diffusion barriers that contain multiple layers, e.g., many layers such as tens or hundreds of layers, may be referred to as laminates. A laminate may contain layers of at least two different barrier materials, and may have from 8 to 1000 total layers with each layer having a thickness, for example, in a range from 0.1 to 10 nanometers.

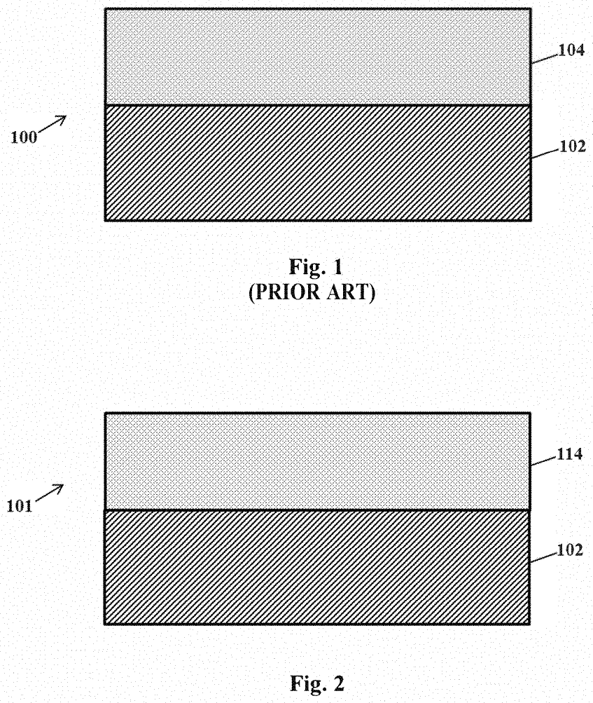

Referring to FIG. 1, illustrated is a typical process chamber component 100 that includes diffusion barrier 104 disposed at a surface of solid body 102 that is made of a solid material (e.g., metal, a metal alloy, glass, quartz, ceramic, etc.). The solid material of solid body 102 includes impurities such as trace metal impurities. Diffusion barrier 104 is a layer made from of a single oxide compound, such as aluminum oxide, that prevents the release of a trace metal impurity from solid body 102.

FIG. 2 shows an exemplary process chamber component 101 (or another type of device or article) made of solid body 102 and diffusion barrier 114, which includes two or more different barrier materials as described herein according to the various embodiments.

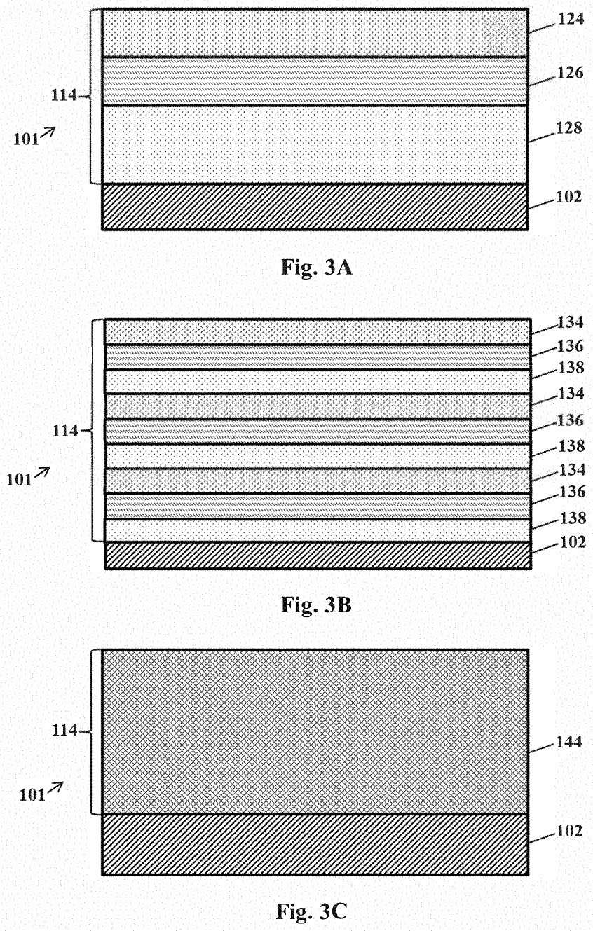

As shown in more detail at FIG. 3A, according to some embodiments, process chamber component 101 may be made of solid body 102 and diffusion barrier 114, which is made of two or three different barrier materials formed into multiple (three as illustrated) layers. Layers 124, 126, and 128 can be made of at least two different barrier materials, with each of the different layers being made of a single barrier material. For example, each of layers 124, 126, and 128 can be made of a different barrier material: one or more of the barrier materials may be an oxide, nitride, or fluoride of yttrium; one or more of the barrier materials may be an oxide, nitride, or fluoride of aluminum; one or more of the barrier materials may be an oxide, nitride, or fluoride of titanium; one or more of the barrier materials may be an oxide, nitride, or fluoride of zirconium; and one or more of the barrier materials may be an oxide, nitride, or fluoride of tantalum. Each layer can preferably have a high purity, such as a purity of at least 90, 95, 98, or 99 percent by weight of the barrier material. Each layer of barrier material may be continuous over the surface of solid body 102, and may have a thickness in a range of from less than 1 nanometer, e.g., about 1, 2, 5, or 10 nanometers, up to 10, 100, 500, 800, or 900 nanometers (0.9 micron).

Other layers of a different type of barrier material or a non-barrier material are not excluded and may be present but may not be necessary or preferred.

FIG. 3B shows another example process chamber component 101 provided in accordance with an embodiment of the disclosure. Chamber component 101 includes solid body 102 and diffusion barrier 114 made of two or more different barrier materials formed into many (e.g., tens, hundreds, or thousands) individual layers, each of a single barrier material. Layers 134, 136, and 138 can be made of at least two different barrier materials, with each layer being made of a single barrier material. For example, each of layers 134, 136, and 138 can be made of a different barrier material with each of the different layers being made of a single barrier material. One or more of the barrier materials may be an oxide, nitride, or fluoride of yttrium; one or more of the barrier materials may be an oxide, nitride, or fluoride of aluminum; one or more of the barrier materials may be an oxide, nitride, or fluoride of titanium; one or more of the barrier materials may be an oxide, nitride, or fluoride of zirconium; and one or more of the barrier materials may be an oxide, nitride, or fluoride of tantalum. Each layer can preferably have a high purity, such as a purity of at least 90, 95, 98, or 99 percent barrier material by weight. Each layer of barrier may be continuous over the surface of solid body 102 and may have a thickness in a range from of less than 1 nanometer, e.g., from about 0.1, 0.5, 1, 2, 5, or 10 nanometers, up to 10, 15, or 20 nanometers.

Other layers of a different type of barrier material or a non-barrier material are not necessarily excluded and may be present but may not be necessary or preferred.

Diffusion barrier 114 of FIG. 3B, containing tens, hundreds, or thousands of layers, may be referred to as a “laminate” diffusion barrier. A laminate diffusion barrier may be applied to a surface of solid body 102 by a series of atomic layer deposition steps by exposing the surface to a sequence of gaseous precursor materials that will sequentially form each of the individual layers made of a single barrier material. Each continuous amount of deposited barrier material is considered to be a “layer.” By an example, a series of atomic layer deposition steps can be performed, each step using a single precursor materials to form a single barrier layer. The series includes steps of depositing at least two different types of barrier material layers to form the different layers of the laminate. The laminate diffusion barrier includes discrete “layers” due to the multi-step process by which identifiable layers deposited barrier materials are deposited, e.g., in a patterned sequence.

The laminate is considered to be made of different layers, one produced by each atomic layer deposition step, even though the discrete “layers” of different deposited materials may be challenging to identify by use of known techniques. In some laminate coatings, discrete layers may be detectable using a tunneling electron microscope. Each layer may be considered to constitute a “monolayer,” as that term is used on the chemical deposition arts, and which refers to an amount of a deposited material that has been deposited onto a surface of a substrate or to a previous ALD layer such that the deposited material saturates reaction sites on the substrate or previous ALD layer. A monolayer has a thickness of only a small number of atoms, i.e., a thickness of a single layer of atoms or molecules that cover the surface by associating with the limited number of reaction sites at the surface to produce a monolayer having a thickness of not more than about 2, 3, or 5, atoms.

FIG. 3C shows an example of another process chamber component 101 provided in accordance with an embodiment of the disclosure. Chamber component 101 includes solid body 102 and diffusion barrier 114, with diffusion barrier 114 in the form of a composite (144) made of two or more different barrier materials formed into a “composite” form of incomplete layers. The composite can be formed also by atomic layer deposition, as with a “laminate” diffusion barrier, by a series of atomic layer deposition steps, but with the amount of each material that is deposited during each step of the series being an amount that will not produce a uniformly-deposited continuous layer of the deposited barrier material. For example, barrier materials may be deposited by atomic layer deposition steps that deposit an amount of barrier material that has a thickness that is less than a roughness of the surface onto which the barrier material is being deposited. When deposited in succession, deposited amounts of different barrier materials form a “composite” material made from the different deposited materials, but that do not form discrete or continuous layers, e.g., do not form even a monolayer having a thickness of from 1 to 5 atoms thick.

A diffusion barrier 114 in the form of composite 144 of can be made of two or more barrier materials as described. One or more of the barrier materials may be an oxide, nitride, or fluoride of yttrium; one or more of the barrier materials may be an oxide, nitride, or fluoride of aluminum; one or more of the barrier materials may be an oxide, nitride, or fluoride of titanium; one or more of the barrier materials may be an oxide, nitride, or fluoride of zirconium; and one or more of the barrier materials may be an oxide, nitride, or fluoride of tantalum. The composite can preferably have a high purity, such as by containing at least 90, 95, 98, or 99 percent by weight of the two or more barrier materials made to form the diffusion barrier. A total thickness of the diffusion barrier can also be of any useful thickness, such as a thickness in a range of from 10 to 1000 nanometers.

Examples of presently-preferred diffusion barriers made of two (in this instance, only two) different barrier materials may have two layers, multiple layers (e.g., from 3 to 10), or may be a laminate or a composite of the two barrier materials. Each individual layer of a multiple layer diffusion barrier or a laminate may be made from a barrier material chosen from alumina, yttria, zirconia, and titania. For example, a multi-layer or laminate diffusion barrier made using only two barrier materials may be made of alternating layers of: alumina and yttria, alumina and zirconia, alumina and titania, yttrium and zirconia, or yttria and titania. For a diffusion barrier that contains only two total layers (one layer made of each barrier material), each layer may be about 50 nanometers, e.g., from 40 to 60 nanometers. For a diffusion barrier that contains from 3 to 10 layers, each layer may be from 1, 5, or 10 to 20 to 40 nanometers, e.g., from 10 to 30 nanometers. These or a composite diffusion barrier may have a total thickness of from 50 to 150 nanometers, e.g., from 80 to 120 nanometers. The ratio of the number of layers of each of the two barrier materials may be approximately 1:1, e.g., from 40:60 to 60:40, or from 45:55 to 55:45.

Examples of presently-preferred diffusion barriers made of three (in this instance, only three) different barrier materials may have three layers, multiple layers (e.g., from 4 to 10), or may be a laminate or a composite of the three different barrier materials. Each individual layer of a multi-layer diffusion barrier or a laminate may be made from a barrier material chosen from alumina, yttria, zirconia, and titania. For example, a multi-layer, laminate, or composite diffusion barrier made using only three barrier materials may be made of patterned layers of: alumina, zirconia, and yttria; alumina, titania, and yttria, zirconia, titania, and yttria; zirconia, alumina, and titania. For a diffusion barrier that contains only three total layers (one layer made of each barrier material), each layer may be from about 25 to 70 nanometers, e.g., from 30 to 60 nanometers. For a diffusion barrier that contains from 4 to 10 layers, each layer may be from 20 to 45 nanometers, e.g., from 15 to 40 nanometers. These or a composite diffusion barrier may have a total thickness of from 50 to 200 nanometers, e.g., from 80 to 160 nanometers. The amount of the different barrier materials in a diffusion barrier may be approximately 33 weight percent of each barrier material, e.g., from 30 to 40 weight percent of each barrier material in the diffusion barrier.

A diffusion barrier of the present description can be useful when disposed on any article or surface that contains impurities that are desirably prevented from becoming diffused out of the article. A diffusion barrier as described can be particularly useful as a barrier to prevent impurities from escaping a solid body of an article, device, or component (e.g., a “process chamber component”) that is part of a semiconductor processing tool, such as an ion implantation tool or a type of deposition tool, e.g., chemical vapor deposition, physical vapor deposition, atomic layer deposition, etc.

Without limiting the scope of the present description, a semiconductor processing tool can be any type that includes a process chamber, operated at a vacuum, within which a semiconductor substrate is processed. The process chamber operates at a high level of vacuum to contain and allow processing of a semiconductor device by exposing the device to highly pure process materials such as a plasma, ions, or molecular compounds in the form of a gas or vapor, which will be applied to the semiconductor substrate. The process chamber must contain components and surfaces that are useful to transport, hold, secure, support, or move a substrate into, out of, and within the process chamber. The process chamber must also contain a system of structures that is effective to flow, deliver, and remove processing materials (e.g., plasma, ions, gaseous deposition materials, etc.) to and from the vacuum contained by the process chamber. Examples of these different types of process chamber components include a sidewall or liner that defines an interior surface of a process chamber, as well as flow heads (shower heads), shields, trays, supports, nozzles, valves, conduits, stages for handling or holding a substrate, wafer handling fixtures, chamber liners (i.e., sidewalls), ceramic wafer carriers, wafer holders, susceptors, spindles, chucks, rings, baffles, and various types of fasteners (screws, nuts, bolts, clamps, rivets, etc.). Any of these or other types of process chamber components can be adapted to include a diffusion barrier as described herein, to inhibit or prevent passage of impurities from a solid material that forms the process chamber component, into a vacuum environment of a process chamber.

A process chamber component may have any shape or any form of a surface, such as a flat and planar surface (for a liner or sidewall), or may additionally or alternately have a physical shape or form that includes an opening, aperture, channel, tunnel, a threaded screw, a threaded nut, a porous membrane, a filter, a three-dimensional network, a hole, or the like, including such features that are considered to have a high aspect ratio. Atomic layer deposition techniques for providing certain example diffusion barrier as described can be effective to provide a uniform and high quality diffusion barrier on such structures, including articles having structures with an aspect ratio of at least 20:1, 50:1, 100:1, 200:1, or even 500:1.

A diffusion barrier as described may be useful with a process chamber component of any type of semiconductor processing tool, and with a processing tool that operates at any temperature and other process conditions. A diffusion barrier as described may be particularly useful when disposed on a process chamber component of a semiconductor processing tool that operates at elevated temperature, such as a temperature significantly above room temperature. As one example, newer ion implantation methods are performed at increasingly higher temperatures, including temperatures in excess of 300, 400, 500, 600, or 700 degrees Celsius. Various deposition techniques (e.g., chemical vapor deposition, physical vapor deposition, atomic layer deposition) and annealing steps may be performed at temperatures at or above 400, 500, or 600 degrees Celsius. For these methods, performed using a semiconductor processing tool, process chamber components of the tool are exposed to the same high temperatures, which causes an increased diffusion rate of trace metal impurities in a solid material of the process chamber components. An effective barrier material, as presently described, can be especially useful for these processing tools and processing methods.

A process chamber component can be made from a solid material, also referred to as a “solid body” or a “substrate,” of a type sometimes referred to as a “vacuum-compatible substrate.” Generally, examples of solid materials useful as a vacuum-compatible substrate can include ceramic materials, metals (including alloys such as aluminum alloys and solid steel), glass, quartz, and polymer materials. Examples of ceramic materials that can be useful as a vacuum-compatible substrate include alumina, silicon carbide, and aluminum nitride. Examples of metals and metal alloys include stainless steel and aluminum. Vacuum-compatible substrates can also be quartz, sapphire, dielectric materials, conductive materials, silica, fused silica, fused quartz, silicon, anodized aluminum, zirconium oxide, as well as plastics such as certain plastics used in the semiconductor industry, e.g., as polyether ether ketone (PEEK) and polyimides.

As one single example, a diffusion barrier as described can be effective when included at or near a surface of an electrostatic chuck of an ion implantation device, which may be a beam-type ion implantation device or a plasma ion immersion implantation device. As is known, an electrostatic chuck can be contained in a process chamber of an ion implantation device to support and maintain a position of a semiconductor wafer during an ion implantation process.

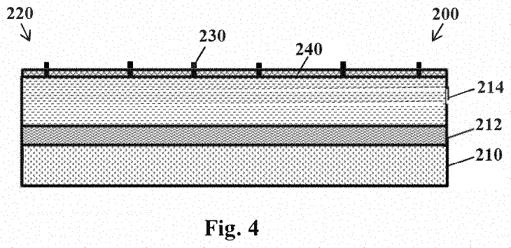

Various general and specific designs of electrostatic chucks are known. Referring to FIG. 4, a typical an electrostatic chuck (200) can be formed of multiple layers that include a base layer 210 of a solid dielectric (e.g., ceramic) material, an adhesive bonding layer, and a second dielectric layer 214. Top surface 220 can include optional embossments 230, which can also be made of a dielectric material. Various other structures and devices, including electrical devices such as conductive layers (e.g., a ground layer, a charge dissipation layer), may also be present.

According to a particular example, a process chamber component in the form of an electrostatic chuck as illustrated at FIG. 4 can include a diffusion barrier 240 at an upper portion of the electrostatic chuck, e.g., at or near an upper surface of second dielectric layer 214. Diffusion barrier 240 can be effective to prevent passage of impurities from dielectric layer 214, into an atmosphere of an ion implantation device that contains electrostatic chuck 200.

Diffusion barrier 240 can be of any composition and form as described herein, e.g., a multi-layer diffusion barrier, a laminate, or a composite.

While the present description refers often to the use of a diffusion barrier in semiconductor manufacturing processes (e.g., ion implantation, deposition steps), semiconductor processing tools, and related process chamber components, the described diffusion barriers are not limited to these items and applications. Various other solid bodies for use in other environments, e.g., at high vacuum environments, may also benefit from a diffusion barrier as described to prevent impurities from passing from the solid body to the vacuum environment.

1. A diffusion barrier comprising at least two different barrier materials, wherein the at least two different barrier materials include:
an yttrium compound selected from an oxide, nitride, or fluoride of yttrium,
an aluminum compound selected from an oxide, nitride, or fluoride of aluminum,
a titanium compound selected from an oxide, nitride, or fluoride of titanium,
a zirconium compound selected from an oxide, nitride, or fluoride of zirconium, or
a tantalum compound selected from an oxide, nitride, or fluoride of tantalum.

2. The diffusion barrier of claim 1, wherein one of the at least two different barrier materials is effective to act as a barrier against a first trace metal impurity, and a second of the at least two barrier materials is effective to act as a barrier against a second trace metal impurity different from the first trace metal impurity.

3. The diffusion barrier of claim 1, comprising:
a first barrier material that is effective as a diffusion barrier to one or more of iron, cobalt, nickel, and copper as an impurity; and
a second barrier material that is effective as a diffusion barrier to one or more of Zn, Mg, Mn, Na, Ca, K as an impurity.

4. The diffusion barrier of claim 1, comprising from 2 to 5 layers of the at least two different barrier materials, and each layer having a thickness in a range from 2 to 10 nanometers.

5. The diffusion barrier of claim 4, comprising two layers or three layers selected from: a zirconia layer, a titania layer, an yttria layer, a tantala layer, and an alumina layer.

6. The diffusion barrier of claim 1, comprising from 8 to 1000 layers of the at least two different barrier materials, and each layer having a thickness in a range from 0.1 to 10 nanometers.

7. The diffusion barrier of claim 6, comprising at least two of: multiple zirconia layers, multiple titania layers, multiple yttria layers, multiple tantala layers, multiple alumina layers.

8. The diffusion barrier of claim 1, comprising the at least two different barrier materials are a composite material.

9. The diffusion barrier of claim 8, comprising barrier materials selected from: zirconia, titania, yttria, tantala, and alumina.

10. The diffusion barrier of claim 1, that consist essentially of at least two different barrier materials including:
an yttrium compound selected from an oxide, nitride, or fluoride of yttrium,
an aluminum compound selected from an oxide, nitride, or fluoride of aluminum,
a titanium compound selected from an oxide, nitride, or fluoride of titanium,
a zirconium compound selected from an oxide, nitride, or fluoride of zirconium, or
a tantalum compound selected from an oxide, nitride, or fluoride of tantalum.

11. The diffusion barrier of claim 1, consist essentially of at least two different barrier materials selected from a zirconia layer, a titania layer, an yttria layer, a tantala layer, or an alumina layer.

12. The diffusion barrier of claim 1, having a thickness of in a range from 5 to 1000 nanometers.

13. An article comprising a substrate having a diffusion barrier, the diffusion barrier comprising at least two different barrier materials including:
an yttrium compound selected from an oxide, nitride, or fluoride of yttrium,
an aluminum compound selected from an oxide, nitride, or fluoride of aluminum,
a titanium compound selected from an oxide, nitride, or fluoride of titanium,
a zirconium compound selected from an oxide, nitride, or fluoride of zirconium, or
a tantalum compound selected from an oxide, nitride, or fluoride of tantalum.

14. The article of claim 13, wherein one of the two different barrier materials is effective to act as a barrier against a first trace metal impurity, and a second of the two different barrier materials is effective to act as a barrier against a second trace metal impurity different from the first trace metal impurity.

15. The article of claim 13, comprising:
a first barrier material that is effective as a diffusion barrier to one or more of iron, cobalt, nickel, and copper as an impurity,
a second barrier material that is effective as a diffusion barrier to one or more of Zn, Mg, Mn, Na, Ca, K as an impurity.

16. The article of claim 13, wherein the article is a process chamber component of a semiconductor manufacturing tool.

17. The article of claim 13, wherein the semiconductor manufacturing tool is an ion implantation device, a deposition chamber, an etch chamber, or a surface modification chamber.

18. The article of claim 13, wherein the process chamber component is selected from: an interior wall surface, a wafer susceptor, an electrostatic chuck, a showerhead, a nozzle, a baffle, a fastener, a wafer transport structure, or a portion or component of any one or these.

19. The article of claim 13, wherein the semiconductor manufacturing tool is an ion implantation device and the component is an electrostatic chuck.
